(19) United States
(12) Patent Application Publication
(10) Pub. No.: US 2025/0015104 A1
(43) Pub. Date: Jan. 9, 2025

(54) SEMICONDUCTOR DEVICE AND PHOTODETECTOR

(71) Applicant: SONY SEMICONDUCTOR SOLUTIONS CORPORATION, KANAGAWA (JP)

(72) Inventors: HIROYUKI OHRI, KANAGAWA (JP); HIROYUKI HATTORI, KANAGAWA (JP)

(21) Appl. No.: 18/709,937

(22) PCT Filed: Nov. 14, 2022
(86) PCT No.: PCT/JP2022/042166

§ 371 Date: May 14, 2024

(30) Foreign Application Priority Data
Nov. 22, 2021 (JP) 2021-189619

(51) Int. Cl. H01L 27/146; H01L 29/861; H04N 25/709

(52) U.S. Cl. CPC H01L 27/14609; H01L 27/14634; H01L 29/8611; H04N 25/709

(57) ABSTRACT

[Problem] To shorten the reverse recovery time of a PN junction diode.

[Solution] A semiconductor device includes: a PN junction diode including an N-type first semiconductor region and a P-type second semiconductor region that are disposed in contact with each other at a PN junction surface, a third semiconductor region that is separated from the first semiconductor region and the second semiconductor region and is provided for discharge in a depletion layer formed around the PN junction surface when a reverse bias voltage is applied to the PN junction diode, a first electrode connected to the first semiconductor region, a second electrode connected to the second semiconductor region, and a third electrode connected to the third semiconductor region.

### TECHNICAL FIELD

The present disclosure relates to a semiconductor device and a photodetector.

### BACKGROUND ART

A semiconductor device including a PN junction diode connected to a switching element is generally used (see PTL 1).

However, when a reverse bias voltage, a PN junction diode may generate a reverse current for discharging in a depletion layer formed around a PN junction surface, which may cause a charging loss of a downstream circuit element (e.g., a capacitor). The reverse current is generated by changing a charge flowing in a forward direction in a forward bias voltage state to a backward direction.

### Citation List

### [Patent Literature]

### [PTL 1]

JP 2019-161125A

### SUMMARY

### Technical Problem

In order to suppress the reverse current, in PTL 1, a life time killer is provided around the PN junction diode and recombines minor carriers to reduce the reverse current. The life time killer can be implemented by providing, for example, a crystal defect layer in a semiconductor substrate on purpose. However, in order to form a crystal defect layer, metals or the like need to be implanted into the semiconductor substrate. If semiconductor elements other than a PN junction diode are mounted on the semiconductor substrate, the semiconductor elements may adversely affect the electrical characteristics of other semiconductor elements.

Hence, the present disclosure provides a semiconductor device and a photodetector that can shorten the reverse recovery time of a PN junction diode without adversely affecting other semiconductor elements to be mounted.

### Solution to Problem

In order to solve the problem, the present disclosure provides a semiconductor device including: a PN junction diode including an N-type first semiconductor region and a P-type second semiconductor region that are disposed in contact with each other at a PN junction surface; and
a third semiconductor region that is separated from the first semiconductor region and the second semiconductor region and is provided for discharge in a depletion layer formed around the PN junction surface when a reverse bias voltage is applied to the PN junction diode;
a first electrode connected to the first semiconductor region;
a second electrode connected to the second semiconductor region; and
a third electrode connected to the third semiconductor region.

The third semiconductor region may be disposed as high as the first semiconductor region and the second semiconductor region and may be disposed closer to the second semiconductor region than the first semiconductor region.

The third semiconductor region may be disposed as high as the first semiconductor region and the second semiconductor region and may be disposed to surround the first semiconductor region and the second semiconductor region.

The first semiconductor region and the second semiconductor region may be disposed near the first principal surface of a semiconductor substrate, and the third semiconductor region may be disposed near a second principal surface opposite to the first principal surface of the semiconductor substrate.

The first semiconductor region and the second semiconductor region may be disposed near the first principal surface of a semiconductor substrate, and the third semiconductor region may be disposed near a second principal surface opposite to the first principal surface of the semiconductor substrate and may be disposed to surround the first semiconductor region and the second semiconductor region from a side of the second principal surface to a side of the first principal surface.

The first semiconductor region, the second semiconductor region, and the third semiconductor region may be disposed are disposed at the same layer height,
the second semiconductor region may be disposed to surround the first semiconductor region, and
the third semiconductor region may be disposed to surround the second semiconductor region.

The semiconductor device may include: a well region in which the first semiconductor region, the second semiconductor region, and the third semiconductor region are disposed, and
an element isolation region disposed to surround the well region.

The element isolation region may be as deep as or deeper than the first semiconductor region and the second semiconductor region.

The element isolation region may be as deep as or deeper than the well region.

The element isolation region may be disposed to penetrate the semiconductor substrate where the well region is disposed.

The third semiconductor region may be N-type, and the third electrode may discharge electrons in the depletion layer through the third semiconductor region when the reverse bias voltage is applied to the PN junction diode.

The first electrode may be a cathode electrode, and the third electrode may be set at a higher voltage than the cathode electrode when the reverse bias voltage is applied to the PN junction diode.

The third electrode may be set at the same voltage as the cathode electrode when a forward bias voltage is applied to the PN junction diode, and the third electrode may be set at a higher voltage than the cathode electrode when the reverse bias voltage is applied to the PN junction diode.

The third semiconductor region may be P-type, and the third electrode may discharge holes in the depletion layer through the third semiconductor region when the reverse bias voltage is applied to the PN junction diode.

The second electrode may be an anode electrode, and the third electrode may be set at a lower voltage than the anode electrode when the reverse bias voltage is applied to the PN junction diode.

The third electrode may be set at the same voltage as the anode electrode when a forward bias voltage is applied to the PN junction diode, and the third electrode may be set at a lower voltage than the anode electrode when the reverse bias voltage is applied to the PN junction diode.

The present disclosure provides a photodetector including: a light receiving element that receives an inputted optical signal; and
a voltage generating unit that generates a reverse bias voltage to be applied to the light receiving element,
wherein the voltage generating unit includes a charge pump that generates the reverse bias voltage with the PN junction diodes cascaded in multiple stages in the semiconductor device.

The photodetector may include: a first substrate; and
a second substrate stacked on the first substrate,
wherein the first substrate may have a light receiving unit including the plurality of light receiving elements arranged in a one-dimensional or two-dimensional direction, and at least a part of the charge pump, and
the second substrate may have a logic circuit driven at a voltage level lower than the absolute value of the reverse bias voltage.

The charge pump may include:
a plurality of capacitors, each being connected between the stages of the PN junction diodes cascaded in the multiple stages; and
a plurality of switches that switch the voltages of one ends of the plurality of capacitors,
the plurality of capacitors may be disposed on the first substrate, and
the plurality of switches may be disposed on the second substrate.

The first substrate may have an isolation layer that is disposed between at least some of the stages of the PN junction diodes in the multiple stages and extends in the depth direction of the first substrate.

### BRIEF DESCRIPTION OF DRAWINGS

FIG. 1A is a cross-sectional view of a semiconductor device according to a first embodiment.

FIG. 1B is a plan view of the semiconductor device according to the first embodiment.

FIG. 2 is a voltage waveform diagram of each terminal of the semiconductor device according to the first embodiment.

FIG. 3 shows a change of cathode current when a forward bias voltage or a reverse bias voltage is applied to a PN junction diode.

FIG. 4A shows a charge state in a Player and an N layer when a forward bias voltage is applied.

FIG. 4B shows a charge state in the Player and the N layer when a reverse bias voltage is applied.

FIG. 4C shows a charge state when a recombination level including a crystal defect is formed in the Player or the N layer.

FIG. 5 shows a change of an anode voltage and a cathode current over time.

FIG. 6A is a cross-sectional view of a semiconductor device according to a second embodiment.

FIG. 6B is a plan view of the semiconductor device according to the second embodiment.

FIG. 7 is a cross-sectional view of a semiconductor device according to a third embodiment.

FIG. 8 is a cross-sectional view of a semiconductor device according to a fourth embodiment.

FIG. 9A is a cross-sectional view of a semiconductor device according to a fifth embodiment.

FIG. 9B is a plan view of the semiconductor device according to the fifth embodiment.

FIG. 10 is a cross-sectional view of a semiconductor device according to a sixth embodiment.

FIG. 11A is a block diagram illustrating a schematic configuration of a charge pump including a plurality of PN junction diodes.

FIG. 11B is a cross-sectional view of a part indicated by a broken line in the charge pump of FIG. 11A.

FIG. 12 is a cross-sectional view of a semiconductor device according to an eighth embodiment.

FIG. 13 is a cross-sectional view of a semiconductor device according to a ninth embodiment.

FIG. 14 is a waveform diagram of an anode voltage, a cathode voltage, and a voltage of a discharge terminal.

FIG. 15 is a cross-sectional view of a semiconductor device according to an eleventh embodiment.

FIG. 16 is a voltage waveform diagram of each terminal of the semiconductor device according to the eleventh embodiment.

FIG. 17 is a timing chart of a semiconductor device according to a twelfth embodiment.

FIG. 18A is a cross-sectional view of a semiconductor device according to a thirteenth embodiment.

FIG. 18B is a plan view of the semiconductor device according to the thirteenth embodiment.

FIG. 19 is a voltage waveform diagram of each terminal of the semiconductor device according to the thirteenth embodiment.

FIG. 20 is a block diagram illustrating a schematic configuration of a photodetector.

FIG. 21 is a perspective view schematically illustrating the laminated structure of a semiconductor chip.

FIG. 22A is a circuit diagram of a charge pump.

FIG. 22B shows an example of a specific configuration of a plurality of switches in the charge pump.

FIG. 23 is a cross-sectional view of a first substrate of the photodetector in FIG. 20.

FIG. 24 is a cross-sectional view illustrating a cross-section structure of a capacitor corresponding to a PN junction diode in the charge pump.

FIG. 25 is a block diagram illustrating a schematic configuration of a ranging device.

FIG. 26 is a block diagram illustrating an example of a schematic configuration of a vehicle control system.

FIG. 27 is an explanatory diagram illustrating an example of the installation positions of a vehicle external information detection unit and imaging units.

### DESCRIPTION OF EMBODIMENTS

Embodiments of a semiconductor device and a photodetector will be described below with reference to the accompanying drawings. Hereinafter, the principal components of the semiconductor device and the photodetector will be mainly described. The semiconductor device and the photodetector may include components and functions that are not illustrated or described. The following description does not exclude components or functions that are not illustrated or described.

### First Embodiment

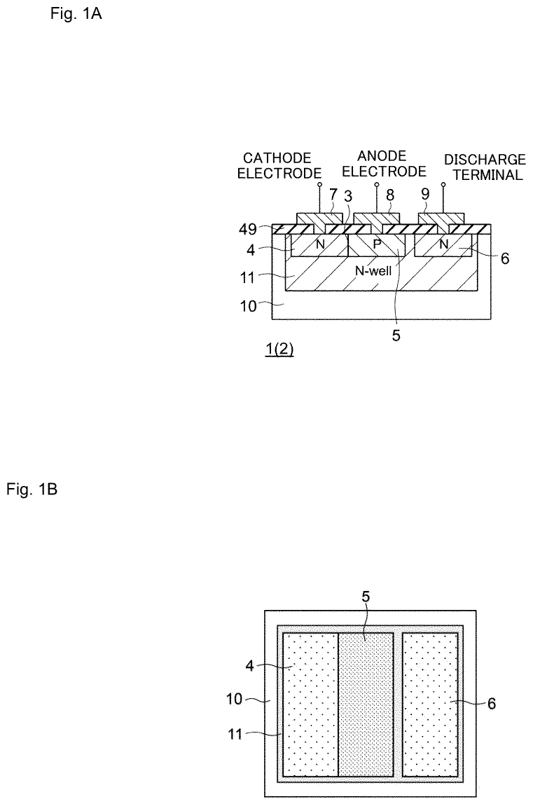

FIG. 1A is a cross-sectional view illustrating a semiconductor device 1 according to a first embodiment. FIG. 1B is a plan view of the semiconductor device 1 according to the first embodiment. FIG. 2 is a voltage waveform diagram of the terminals of the semiconductor device 1 according to the first embodiment.

As illustrated in FIG. 1A, the semiconductor device 1 according to the first embodiment includes a PN junction diode 2. The PN junction diode 2 includes an N-type first semiconductor region 4 and a P-type second semiconductor region 5 that are disposed in contact with each other at a PN junction surface 3.

The semiconductor device 1 according to the first embodiment further includes an N-type third semiconductor region 6, a first electrode 7 connected to the first semiconductor region 4, a second electrode 8 connected to the second semiconductor region 5, and a third electrode 9 connected to the third semiconductor region 6.

The third semiconductor region 6 is separated from the first semiconductor region 4 and the second semiconductor region 5 and is provided for discharge in a depletion layer formed around the PN junction surface 3 when a reverse bias voltage is applied to the PN junction diode 2. The surfaces of the first to third semiconductor regions 4 to 6 are covered with a protective layer 49.

As illustrated in FIGS. 1A and 1B, the third semiconductor region 6 is disposed as high as the first semiconductor region 4 and the second semiconductor region 5 and near the second semiconductor region 5. FIG. 1B illustrates an example in which the first to third semiconductor regions 4 to 6 are rectangular. The shapes and sizes of the first to third semiconductor regions 4 to 6 are not limited to those illustrated in FIGS. 1A and 1B.

The first to third semiconductor regions 4 to 6 are, for example, diffusion layers disposed in an N-type well region 11 on a semiconductor substrate 10. The semiconductor substrate 10 may be N-type or P-type.

Hereinafter, the first electrode 7 may be referred to as a cathode electrode 7, the second electrode 8 may be referred to as an anode electrode 8, and the third electrode 9 may be referred to as a discharge terminal 9. Moreover, the first semiconductor region 4 may be referred to as an N layer, the second semiconductor region 5 may be referred to as a Player, and the third semiconductor region 6 may be referred to as an N layer.

As illustrated in FIG. 2, the cathode electrode 7 is fixed at a reference voltage (e.g., a ground voltage). The anode electrode 8 is set at a voltage higher than the ground voltage if a forward bias voltage is applied to the PN junction diode 2, whereas the anode electrode 8 is set at a lower voltage than the ground voltage if a reverse bias voltage is applied to the PN junction diode 2. The discharge terminal 9 is set at a voltage higher than a cathode voltage. In the example of FIG. 2, the voltage of the discharge terminal 9 is fixed.

If a reverse bias voltage is applied to the PN junction diode 2, a depletion layer is formed near the PN junction surface 3, and a reverse current flows until holes and electrons disappear in the depletion layer. A reverse current is a current generated by electrons flowing into the first semiconductor region 4 to which the cathode electrode 7 is connected and holes flowing into the second semiconductor region 5 to which the anode electrode 8 is connected.

When a reverse bias voltage is applied to the PN junction diode 2, a voltage higher than the cathode voltage is applied to the discharge terminal 9, so that electrons in the depletion layer flow into the third semiconductor region 6 without flowing into the first semiconductor region 4. Thus, backflow of electrons to the cathode electrode 7 can be suppressed.

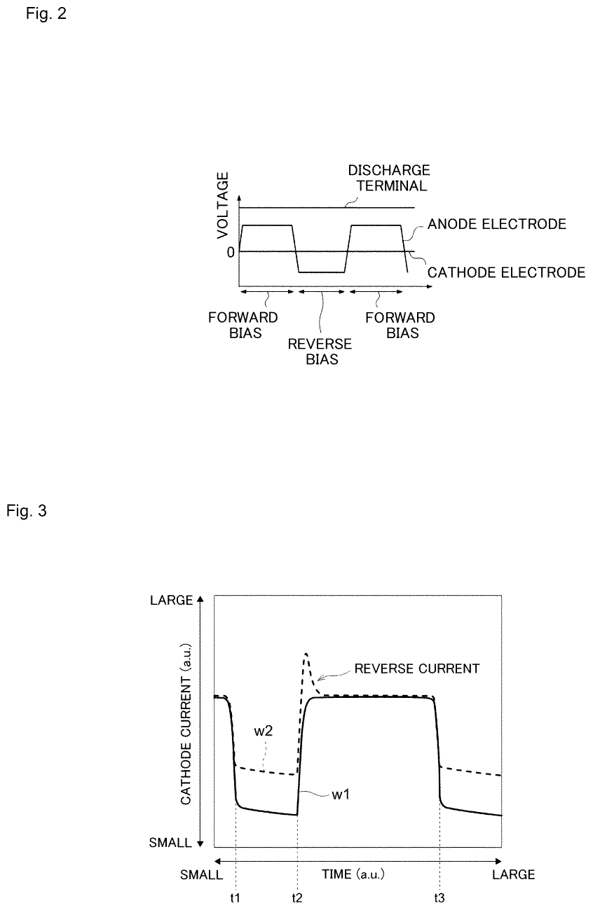

FIG. 3 shows a change of cathode current when a forward bias voltage or a reverse bias voltage is applied to the PN junction diode 2. In FIG. 3, the horizontal axis indicates a time and the vertical axis indicates a cathode current. A period from times t1 to t2 in FIG. 3 indicate a forward bias voltage application period, and times t2 to t3 indicate a reverse bias voltage application period. A waveform w1 indicates the characteristics of the PN junction diode 2 according to the first embodiment, and a waveform w2 indicates the characteristics of a PN junction diode according to a comparative example in which the third semiconductor region 6 and the discharge terminal 9 are not provided.

In the PN junction diode 2 according to the present embodiment, as indicated by the waveform w1, a reverse current is not generated at time t2 when a forward bias voltage is switched to a reverse bias voltage, whereas in the PN junction diode 2 according to the comparative example, as indicated by the waveform w2, an overshooting reverse current is generated at time t2. When a reverse current is generated, electrons flow into, for example, the cathode electrode 7 and thus may adversely affect the operations of a downstream circuit connected to the cathode electrode 7.

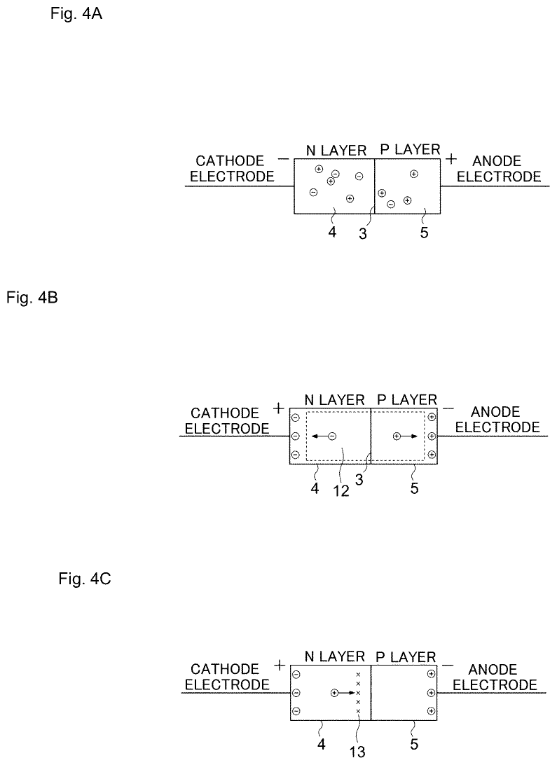

FIGS. 4A, 4B, and 4C are explanatory drawings of a charge state of the PN junction diode 2 according to a comparative example. FIG. 4A shows a charge state in the Player 5 and the N layer 4 when a forward bias voltage is applied. FIG. 4B shows a charge state in the Player 5 and the N layer 4 when a reverse bias voltage is applied. As shows in FIG. 4B, when a reverse bias voltage is applied, a depletion layer 12 is formed around the PN junction surface 3, a charge in the depletion layer 12 moves to the cathode electrode 7 and the anode electrode 8, and a reverse current flows until a completely depleted state is obtained.

In order to suppress a reverse current, as shown in, for example, FIG. 4C, a recombination level 13 including a crystal defect may be formed in the Player 5 or the N layer 4. The recombination level 13 can reduce a reserve current in order to trap holes or electrons in the depletion layer 12. However, in order to form a crystal defect in the Player 5 or the N layer 4, heavy metals or the like need to be implanted and dispersed in the semiconductor substrate 10, thereby causing damage to the semiconductor substrate 10. Thus, the electrical characteristics of semiconductor elements other than the PN junction diode 2 on the same semiconductor substrate 10 may be deteriorated. For this reason, in the semiconductor device 1 according to the present disclosure, a reverse current is suppressed by a technique other than the formation of the recombination level 13.

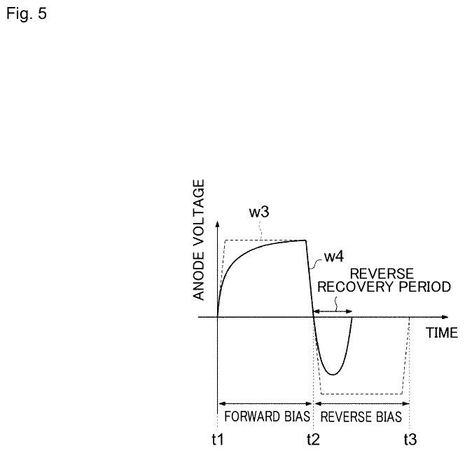

FIG. 5 shows a change of an anode voltage and a cathode current over time. In FIG. 5, a broken-line waveform w3 indicates an anode voltage waveform, and a solid-line waveform w4 indicates a cathode current waveform. Times t1 to t2 in FIG. 5 indicate the application period of a forward bias voltage, and times t2 to t3 indicate the application period of a reverse bias voltage. A period during which a reverse current flows in a period from time t2 to time t3 is also referred to as a reverse recovery period. The reverse current flowing in the period from time t2 to time t3 is generated until electrons and holes in the depletion layer 12 return to the N layer or the Player and are discharged from the cathode electrode 7 and the anode electrode 8.

In the present embodiment, as illustrated in FIG. 1, the discharge terminal 9 is set at a voltage higher than the cathode voltage when a reverse bias voltage is applied, so that electrons in the depletion layer 12 flow into the third semiconductor region 6 without flowing into the first semiconductor region 4. This can suppress a reverse current flowing to the cathode electrode 7 during the application of a reverse bias voltage, thereby shortening a reverse recovery time. By suppressing a reverse current flowing to the cathode electrode 7, a reverse current passing through a downstream circuit, which is connected to the cathode electrode 7 of the PN junction diode 2 in FIG. 1 and is not illustrated, can be suppressed, thereby preventing an adverse effect on the downstream circuit. For example, if the downstream circuit includes a capacitor, a charging loss caused by electrons flowing into the capacitor can be suppressed.

As described above, in the semiconductor device 1 according to the first embodiment, the third semiconductor region 6 is provided in addition to the first semiconductor region 4 and the second semiconductor region 5 that constitute the PN junction diode 2, and a voltage higher than the cathode voltage is applied to the discharge terminal 9, which is connected to the third semiconductor region 6, when a reverse bias voltage is applied, so that electrons in the depletion layer 12 flow into the discharge terminal 9 from the third semiconductor region 6 without flowing into the cathode electrode 7 from the first semiconductor region 4. This can suppress a reverse current flowing to the cathode electrode 7, thereby shortening a reverse recovery time and preventing an adverse effect on a downstream circuit of the PN junction diode 2.

### Second Embodiment

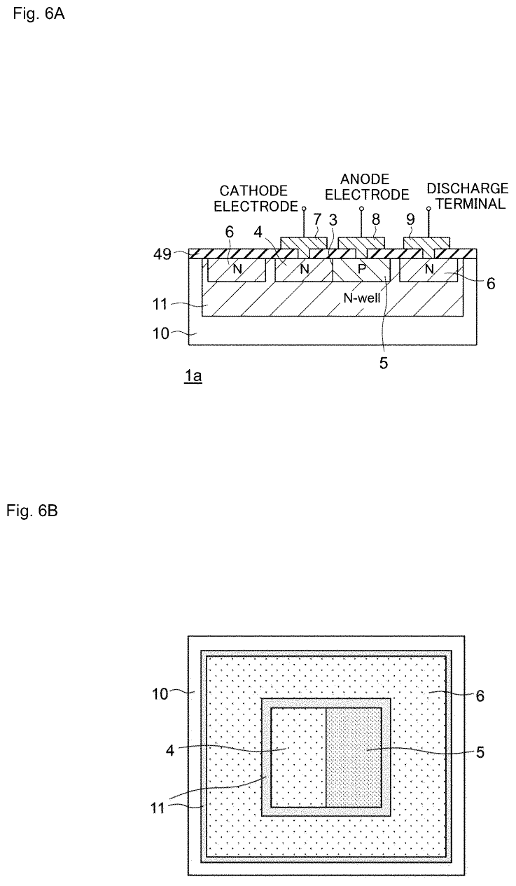

FIG. 6A is a cross-sectional view illustrating a semiconductor device 1a according to a second embodiment. FIG. 6B is a plan view of the semiconductor device 1a according to the second embodiment. Like the semiconductor device 1 according to the first embodiment, the semiconductor device 1a according to the second embodiment includes a first semiconductor region 4, a second semiconductor region 5, and a third semiconductor region 6 that are disposed at the same layer height.

As illustrated in FIGS. 6A and 6B, the semiconductor device 1a according to the second embodiment is different from the semiconductor device 1 according to the first embodiment in that the third semiconductor region 6 is disposed around the first semiconductor region 4 and the second semiconductor region 5.

In the semiconductor device 1a according to the second embodiment, when a reverse bias voltage is applied to a PN junction diode 2 in the semiconductor device 1a, a voltage higher than a cathode voltage is applied to a discharge terminal 9 connected to the third semiconductor region 6, as in the first embodiment.

Since the third semiconductor region 6 is disposed around the first semiconductor region 4 as well as the second semiconductor region 5, electrons in a depletion layer 12 of the PN junction diode 2 are more likely to flow into the discharge terminal 9 from the third semiconductor region 6 during the application of a reverse bias voltage, thereby further suppressing a reverse current to a cathode electrode 7.

As described above, the semiconductor device 1a according to the second embodiment has the third semiconductor region 6 surrounding the first semiconductor region 4 and the second semiconductor region 5, thereby improving the capability of discharging a reverse current when a reverse bias voltage is applied to the PN junction diode 2.

### Third Embodiment

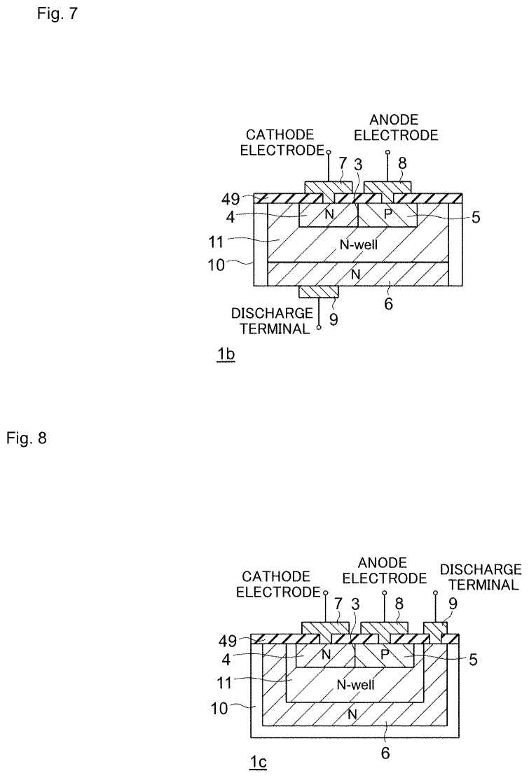

FIG. 7 is a cross-sectional view of a semiconductor device 1b according to a third embodiment. The semiconductor device 1b of FIG. 7 is different from the semiconductor devices 1 and 1a according to the first and second embodiment in the location of a third semiconductor region 6. The third semiconductor region 6 of FIG. 7 is disposed on a second principal surface opposite to a first principal surface where a first semiconductor region 4 and a second semiconductor region 5 are disposed. Moreover, a first electrode 7 (cathode electrode 7) connected to the first semiconductor region 4 and a second electrode 8 (anode electrode 8) connected to the second semiconductor region 5 are disposed on the first principal surface, whereas a third electrode 9 (discharge terminal 9) connected to the third semiconductor region 6 is disposed on the second principal surface.

In the semiconductor device 1b according to the third embodiment, the first to third electrodes 7 to 9 do not need to be disposed along the same surface. Thus, the area of the semiconductor device 1b can be smaller than those of the semiconductor devices 1 and 1a, achieving downsizing. Moreover, the third semiconductor region 6 can be disposed to face a PN junction surface 3 of a PN junction diode 2. Thus, a voltage higher than a cathode voltage is applied to the discharge terminal 9 during the application of a reverse bias voltage, so that electrons in a depletion layer 12 of the PN junction diode 2 can be more efficiently discharged to the discharge terminal 9 through the third semiconductor region 6. This can suppress a reverse current flowing to the cathode electrode 7, thereby shortening a reverse recovery time.

### Fourth Embodiment

FIG. 8 is a cross-sectional view of a semiconductor device 1c according to a fourth embodiment. In the semiconductor device 1c of FIG. 8, a first semiconductor region 4 and a second semiconductor region 5 are disposed near a first principal surface of a semiconductor substrate 10. A third semiconductor region 6 is disposed near a second principal surface opposite to the first principal surface of the semiconductor substrate 10 and is disposed as a relief surrounding the first semiconductor region 4 and the second semiconductor region 5 from the second principal surface to the first principal surface.

More specifically, the first semiconductor region 4 and the second semiconductor region 5 are disposed in an N-type well region 11, and the third semiconductor region 6 is disposed to cover the bottom and sides of the N-type well region 11.

As described above, in the semiconductor device 1c of FIG. 8, the third semiconductor region 6 is disposed like a relief surrounding the first semiconductor region 4 and the second semiconductor region 5 near the first principal surface. Thus, the third semiconductor region 6 is disposed near the sides and bottom of the first semiconductor region 4 connected to a cathode electrode 7. A voltage higher than a cathode voltage is applied to a discharge terminal 9 during the application of a reverse bias voltage, so that electrons in a depletion layer 12 of the PN junction diode 2 are more likely to flow into the third semiconductor region 6. Therefore, the semiconductor device 1c according to the fourth embodiment can improve the capability of discharging electrons through the discharge terminal 9 and suppress a reverse current flowing to the cathode electrode 7 as compared with the semiconductor devices 1, 1a, and 1b according to the first to third embodiments.

### Fifth Embodiment

A semiconductor device 1d according to a fifth embodiment is partially changed from the structure of the semiconductor device 1a according to the second embodiment.

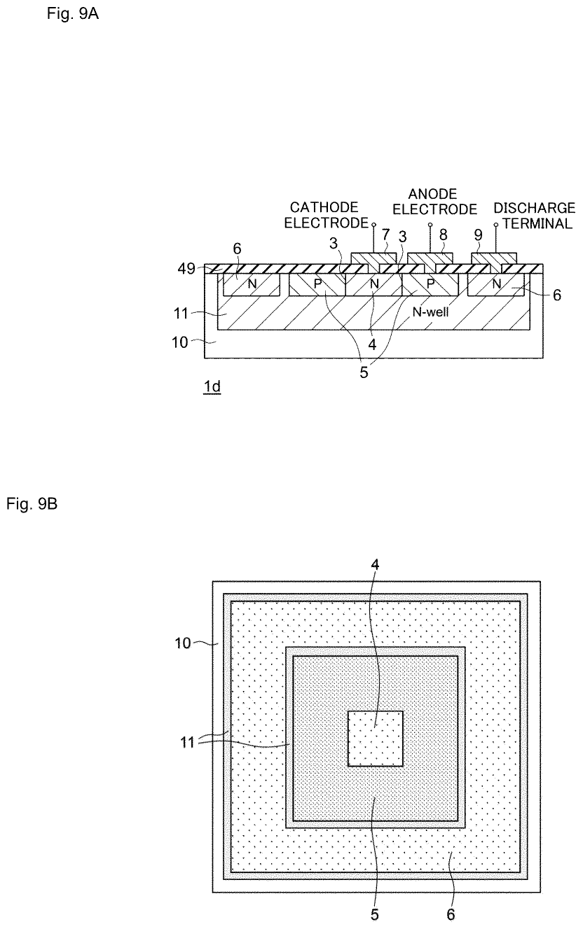

FIG. 9A is a cross-sectional view of the semiconductor device 1d according to the fifth embodiment. FIG. 9B is a plan view of the semiconductor device 1d according to the fifth embodiment.

As illustrated in FIGS. 9A and 9B, the semiconductor device 1d according to the fifth embodiment includes a second semiconductor region 5 disposed around a first semiconductor region 4. Thus, a PN junction surface 3 of the first semiconductor region 4 and the second semiconductor region 5 is disposed around the first semiconductor region 4. A first electrode 7 (cathode electrode 7) is connected to the first semiconductor region 4, and a second electrode 8 (anode electrode 8) is connected to the second semiconductor region 5.

As illustrated in FIGS. 9A and 9B, the semiconductor device 1d according to the fifth embodiment further includes a third semiconductor region 6 disposed around the second semiconductor region 5. In other words, the third semiconductor region 6 is disposed around the PN junction surface 3. A third electrode 9 (discharge terminal 9) is connected to the third semiconductor region 6.

When a reverse bias voltage is applied to a PN junction diode 2, electrons in a depletion layer 12 formed around the PN junction surface 3 can be more efficiently discharged from the third semiconductor region 6 to the discharge terminal 9.

Specifically, in the semiconductor device 1d according to the fifth embodiment, the area of the PN junction surface 3 is extended and the third semiconductor region 6 is disposed to face the overall PN junction surface 3, so that electrons in the depletion layer 12 formed around the PN junction surface 3 are easily moved to the third semiconductor region 6. Moreover, in the semiconductor device 1d according to the fifth embodiment, the PN junction surface 3 of the PN junction diode 2 in the semiconductor device 1d has a large area, thereby increasing a forward current when a forward bias voltage is applied. Thus, the charging time of a downstream circuit charged by a forward current from the semiconductor device 1d according to the fifth embodiment is shortened, enabling a high-speed operation of the downstream circuit.

### Sixth Embodiment

In a sixth embodiment, an element isolation region is provided around a semiconductor device 1e according to any one of the first to fifth embodiments.

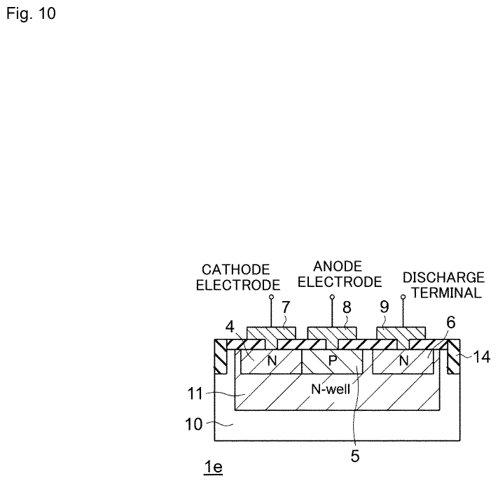

FIG. 10 is a cross-sectional view of the semiconductor device 1e according to the sixth embodiment. The cross-section structure of the semiconductor device 1e in FIG. 10 is identical to that of FIG. 1A. The cross-section structure of the semiconductor device 1e according to the sixth embodiment can be identical to that of FIG. 6A, 7, 8, or 9.

As illustrated in FIG. 10, the semiconductor device 1e according to the sixth embodiment includes an element isolation region 14 disposed to face the side of a well region 11 in which a first semiconductor region 4, a second semiconductor region 5, and a third semiconductor region 6 are disposed. In other words, the element isolation region 14 is disposed to surround the semiconductor device 1e according to the sixth embodiment. The element isolation region 14 in FIG. 10 is also referred to as STI (Shallow Trench Isolation).

The depth of the element isolation region 14 is smaller than that of the well region 11 and is as large as, for example, the depths of the first to third semiconductor regions 4 to 6. The element isolation region 14 is formed such that a trench is formed from the surface of a semiconductor substrate 10 in the depth direction by etching or the like and the trench is filled with an insulating material, e.g., SiO₂. The element isolation region 14 may have a multilayer structure formed by filling the trench with an insulating material and a conductive material.

The provision of the element isolation region 14 in FIG. 10 can restrict a region in which forward carriers spread during the application of a forward bias voltage to the PN junction diode 2 in the semiconductor device 1e, so that charge in a depletion layer 12 is easily discharged to a discharge terminal 9 through the third semiconductor region 6 during the application of a reverse bias voltage.

### Seventh Embodiment

A semiconductor device 1f may include a plurality of PN junction diodes 2. If the semiconductor device 1f includes the plurality of PN junction diodes 2, the PN junction diodes 2 are desirably isolated by an element isolation region 14.

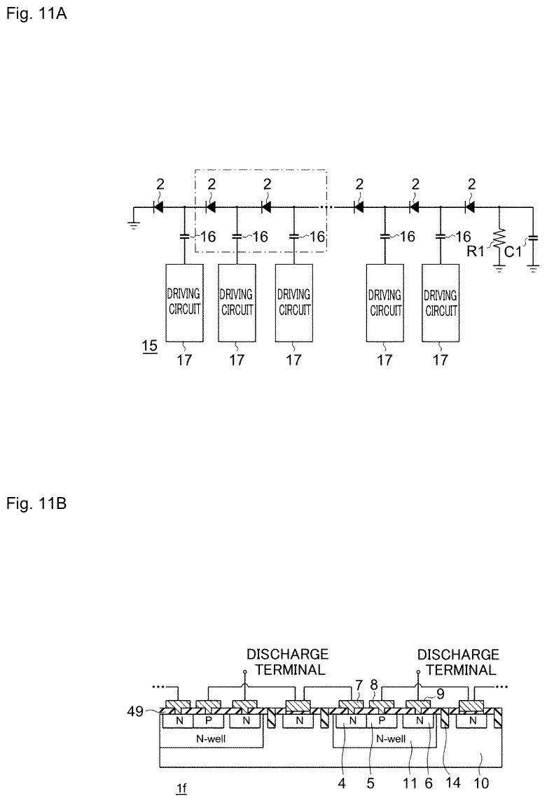

FIG. 11A is a block diagram illustrating a schematic configuration of a charge pump 15 including the plurality of PN junction diodes 2. The charge pump 15 in FIG. 11A includes the PN junction diodes 2 cascaded in multiple stages, a plurality of capacitors 16, each being connected between the stages of the PN junction diodes 2 cascaded in the multiple stages, and a plurality of driving circuits 17 connected in series with the plurality of capacitors 16.

One end of the capacitor 16 is connected to the connection node of the two corresponding PN junction diodes 2. The other end of the capacitor 16 is connected to the corresponding driving circuits 17. The driving circuit 17 switches, for example, whether to apply a predetermined voltage or a ground voltage to the other end of the corresponding capacitor 16.

FIG. 11B is a cross-sectional view of a part indicated by a broken line in the charge pump 15 of FIG. 11A. For example, the PN junction diode 2 in the charge pump 15 of FIG. 11B has the same cross-section structure as FIG. 1A. The PN junction diode 2 in FIG. 11A may have the same cross-section structure as FIG. 6A, 7, 8, or 9A. As illustrated in FIG. 11B, the PN junction diodes 2 in multiple stages and the plurality of capacitors 16 in the charge pump 15 are alternately disposed in the planar direction of a semiconductor substrate 10.

As illustrated in FIG. 11B, the PN junction diode 2 in each stage in the charge pump 15 is surrounded by the element isolation region 14 that extends from the surface of the semiconductor substrate 10 in the depth direction. Thus, when a forward bias voltage is applied to the PN junction diode 2, the diffusion of a forward current can be suppressed by the element isolation region 14. Thus, a charge in a depletion layer 12 formed during the application of a reverse bias voltage to the PN junction diode 2 can be quickly discharged to a discharge terminal 9 through a third semiconductor region 6.

### Eighth Embodiment

An element isolation region 14 may be formed deeper than the element isolation regions 14 according to the sixth and seventh embodiments.

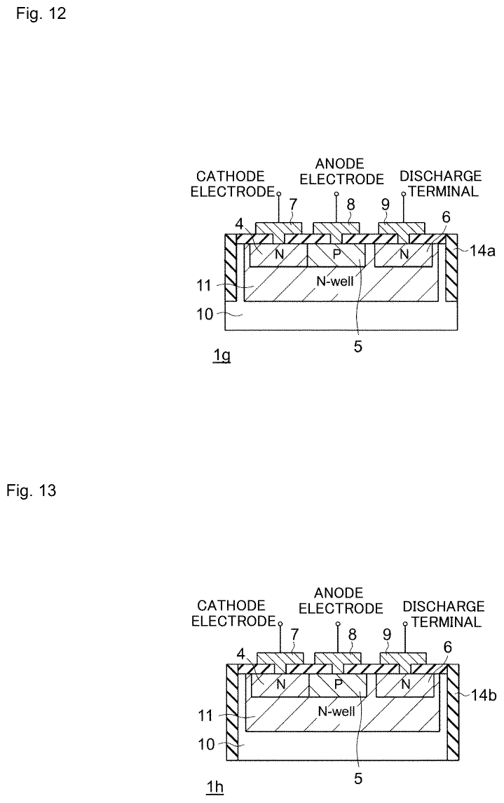

FIG. 12 is a cross-sectional view of a semiconductor device 1g according to the eighth embodiment. The semiconductor device 1g of FIG. 12 includes an element isolation region 14a disposed to a deeper position than the element isolation region 14 in the semiconductor device 1e of FIG. 10. The element isolation region 14a of FIG. 12 is formed such that a trench is formed from the surface of a semiconductor substrate 10 in the depth direction and the trench is filled with an insulating material, e.g., SiO₂. The element isolation region 14a of FIG. 12 is disposed to surround a well region 11 in which first to third semiconductor regions 4 to 6 are formed, like the element isolation region 14 of FIG. 10.

The element isolation region 14a is disposed to a deeper position than the well region 11 and is also referred to as DTI (Deep Trench Isolation). However, the element isolation region 14a is not so deep as to penetrate the semiconductor substrate 10.

As described above, the element isolation region 14a is disposed to a deeper position, so that the diffusion of the charge of a forward current can be suppressed by the element isolation region 14a during the application of a forward bias voltage of the PN junction diode 2, and a charge in a depletion layer 12 can be more easily discharged from a discharge terminal 9 through a third semiconductor region 6.

### Ninth Embodiment

In a ninth embodiment, an element isolation region 14b is provided to penetrate a semiconductor substrate 10. Specifically, the element isolation region 14d disposed to surround the semiconductor devices 1 to 1d according to the first to fifth embodiments may be disposed to penetrate the semiconductor substrate 10.

FIG. 13 is a cross-sectional view of a semiconductor device 1h according to the ninth embodiment. The semiconductor device 1h of FIG. 13 is surrounded by the element isolation region 14d that penetrates the semiconductor substrate 10. The element isolation region 14d of FIG. 13 is formed such that a trench formed through the semiconductor substrate 10 is filled with an insulating material, e.g., SiO₂. The element isolation region 14d of FIG. 13 is also referred to as FTI (Full Trench Isolation).

The provision of the element isolation region 14d of FIG. 13 can physically isolate the semiconductor device 1h from other semiconductor elements, so that the element isolation region 14d can completely restrict the diffusion of the charge of a forward current when a forward bias voltage is applied to a PN junction diode 2 in the semiconductor device 1h. Thus, a charge in a depletion layer 12 during the application of a reverse bias voltage to the PN junction diode 2 can be quickly discharged to a discharge terminal 9 through a third semiconductor region 6.

### Tenth Embodiment

The first to ninth embodiments described examples in which a fixed voltage higher than a cathode voltage is applied to the discharge terminal 9. A voltage synchronized with an anode voltage may be applied to the discharge terminal 9.

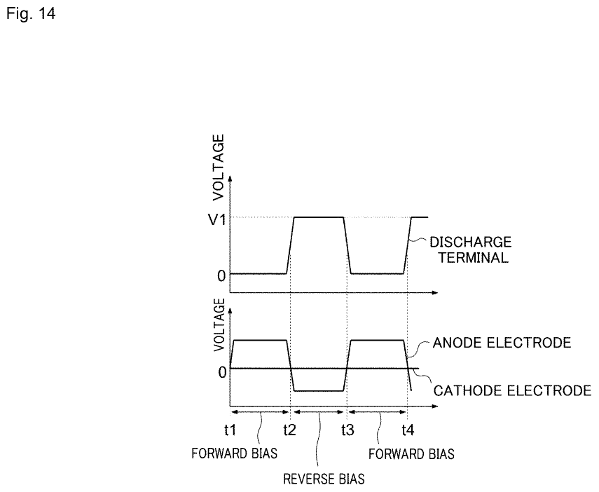

FIG. 14 is a waveform diagram of an anode voltage, a cathode voltage, and a voltage of the discharge terminal 9. A period from time t1 to time t2 and a period from time t3 to time t4 are application periods of a forward bias voltage of a PN junction diode 2. A period from time t2 to time t3 is an application period of a reverse bias voltage of the PN junction diode 2.

In the period of application of a forward bias voltage to the PN junction diode 2, a positive voltage is applied to an anode electrode 8 and a discharge terminal 9 is set at, for example, a ground voltage. In the period of application of a reverse bias voltage to the PN junction diode 2, a negative voltage is applied to the anode electrode 8 and a positive voltage higher than the cathode voltage is applied to the discharge terminal 9. In the application of a forward bias voltage and the application of a reverse bias voltage to the PN junction diode 2, a cathode electrode 7 is set at the ground voltage.

Thus, in a tenth embodiment, a voltage higher than the cathode voltage is applied to the discharge terminal 9 only in the application of a reverse bias voltage to the PN junction diode 2 according to the first to ninth embodiments, and the discharge terminal 9 is set at the ground voltage in the application of a forward bias voltage to the PN junction diode 2. Hence, the period of application of a positive voltage to the discharge terminal 9 can be shortened. More specifically, in the application of a forward bias voltage of the PN junction diode 2, a current flowing to a second semiconductor region 5 from the discharge terminal 9 through a third semiconductor region 6 can be reduced, thereby reducing a current consumed during the application of a forward bias voltage of the PN junction diode 2.

### Eleventh Embodiment

The first to tenths embodiments described examples in which the third semiconductor region 6 is an N-type region. A P-type third semiconductor region 6a may be provided instead.

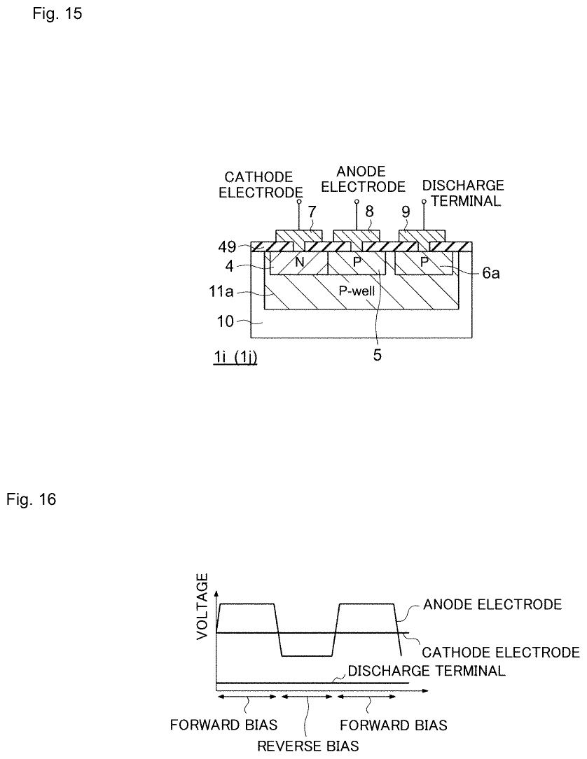

FIG. 15 is a cross-sectional view of a semiconductor device 1i according to an eleventh embodiment. FIG. 16 is a voltage waveform diagram of each terminal of the semiconductor device 1i according to the eleventh embodiment. The semiconductor device 1i of FIG. 15 includes a well region 11 in which a first semiconductor region 4, a second semiconductor region 5, and the third semiconductor region 6a are disposed. As in the first to tenth embodiments, the first semiconductor region 4 to which a first electrode 7 (cathode electrode 7) is connected is N-type, and the second semiconductor region 5 to which a second electrode 8 (anode electrode 8) is connected is P-type. Unlike in the first to tenth embodiments, the third semiconductor region 6a to which a third electrode 9 (discharge terminal 9) is connected is P-type, and a well region 11a is also P-type.

As shown in FIG. 16, the discharge terminal 9 is set at a voltage lower than an anode voltage during the application of a reverse bias voltage. During the application of a reverse bias voltage of the PN junction diode 2, the discharge terminal 9 is set at a voltage lower than the anode voltage, so that holes in a depletion layer 12 do not flow into the anode electrode 8 but are discharged to the discharge terminal 9 through the third semiconductor region 6a. This can reduce a reverse current flowing to the anode electrode 8, thereby shortening a reverse recovery time.

The semiconductor device 1i of FIG. 15 is effective if a downstream circuit of a PN junction diode 2 has, for example, a circuit configuration in which a charging loss may be caused by holes outputted from the anode electrode 8. If a downstream circuit of the PN junction diode 2 has, for example, a circuit configuration in which a charging loss may be caused by electrons outputted from the cathode electrode 7, the semiconductor devices 1 to 1h according to any one of the first to tenth embodiments are effective.

### Twelfth Embodiment

FIG. 16 shows an example in which a fixed voltage is applied to the discharge terminal 9. The voltage of the discharge terminal 9 may be changed in synchronization with an anode voltage.

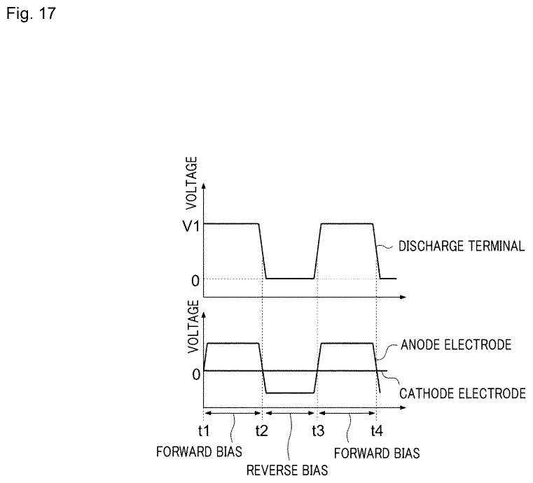

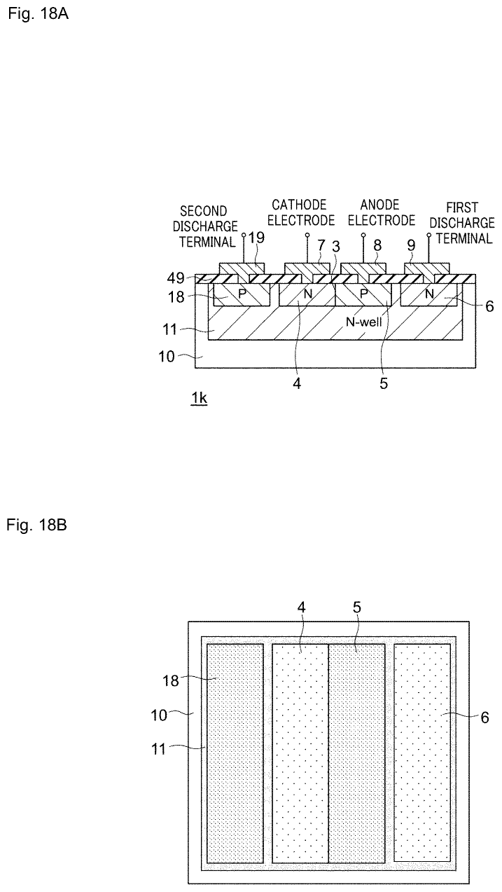

A semiconductor device 1j according to a twelfth embodiment has the same cross-section structure as FIG. 15. FIG. 17 is a timing chart of the semiconductor device 1j according to the twelfth embodiment. A period from time t1 to time t2 and a period from time t3 to time t4 in FIG. 17 are periods of application of a forward bias voltage to a PN junction diode 2. A period from time t2 to time t3 is a period of application of a reverse bias voltage to the PN junction diode 2.

In the period of application of a forward bias voltage to the PN junction diode 2, a discharge terminal 9 is set at a ground voltage. In the period of application of a reverse bias voltage to the PN junction diode 2, a voltage lower than an anode voltage is applied to the discharge terminal 9.

As described above, a voltage lower than the anode voltage is applied to the discharge terminal 9 in the period of application of a reverse bias voltage to the PN junction diode 2, and the discharge terminal 9 is set at the ground voltage in the period of application of a forward bias voltage to the PN junction diode 2. Thus, a current flowing to a second semiconductor region 5 from a third semiconductor region 6 can be reduced in the period of application of a forward bias voltage to the PN junction diode 2, thereby reducing power consumption.

The structures of the semiconductor devices 1i and 1j according to the eleventh and twelfth embodiments may be modified in various forms. For example, as in FIG. 6A, the third semiconductor region 6 in FIG. 15 may be disposed to surround the first semiconductor region 4 and the second semiconductor region 5. Alternatively, as in FIG. 7, the third semiconductor region 6 in FIG. 15 may be disposed near the second principal surface opposite to the first principal surface on which the first semiconductor region 4 and the second semiconductor region 5 are disposed. Alternatively, as in FIG. 8, the third semiconductor region 6 in FIG. 15 may be disposed near the second principal surface and disposed from the second principal surface to the first principal surface as a relief surrounding the first semiconductor region 4 and the second semiconductor region 5. Alternatively, as in FIG. 9A, the first semiconductor region 4 in FIG. 15 may be disposed to surround the second semiconductor region 5 and the third semiconductor region 6 in FIG. 15 may be disposed to surround the first semiconductor region 4. Alternatively, as illustrated in FIGS. 10 to 13, the element isolation region 14 may be disposed to surround the semiconductor device 1j according to the twelfth embodiment.

### Thirteenth Embodiment

In the semiconductor devices 1 to 1j according to the first to twelfth embodiments, only electrons or holes in the depletion layer 12 are discharged to the discharge terminal 9 through the third semiconductor region 6 when a reverse bias voltage is applied to the PN junction diode 2. In contrast, in a semiconductor device 1k according to a thirteenth embodiment described below, both of electrons and holes in a depletion layer 12 are discharged to a discharge terminal 9.

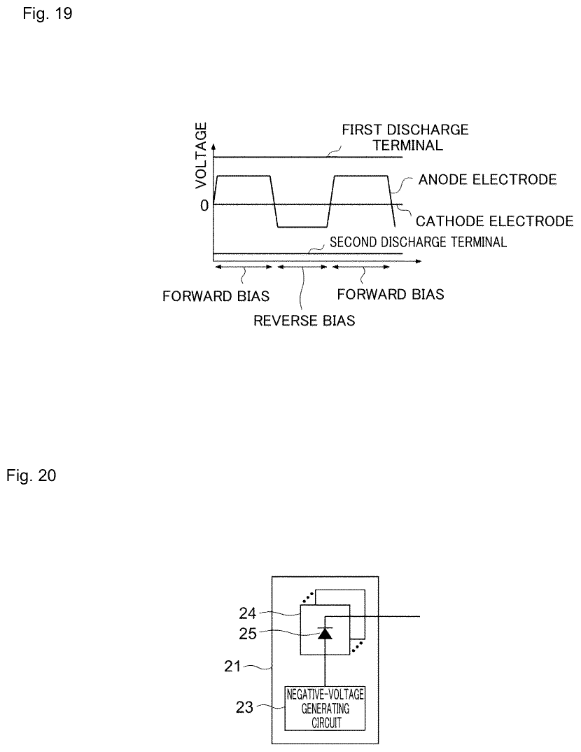

FIG. 18A is a cross-sectional view of the semiconductor device 1k according to the thirteenth embodiment. FIG. 18B is a plan view of the semiconductor device 1k according to the thirteenth embodiment. FIG. 19 is a voltage waveform diagram of each terminal of the semiconductor device 1k according to the thirteenth embodiment.

The semiconductor device 1k according to the thirteenth embodiment includes a third semiconductor region 6, a fourth semiconductor region 18, the third electrode 9 connected to the third semiconductor region 6, and a fourth electrode 19 connected to the fourth semiconductor region 18 in addition to a first semiconductor region 4 and a second semiconductor region 5 that constitute a PN junction diode 2.

The third semiconductor region 6 is an N-type region for discharging electrons in the depletion layer 12 when a reverse bias voltage is applied to the PN junction diode 2. In the present specification, the third electrode 9 connected to the third semiconductor region 6 may be referred to as a first discharge terminal 9.

The fourth semiconductor region 18 is a P-type region for discharging holes in the depletion layer 12 when a reverse bias voltage is applied to the PN junction diode 2. In the present specification, the fourth electrode 19 connected to the fourth semiconductor region 18 may be referred to as a second discharge terminal 19.

As illustrated in FIG. 18A, the first to fourth semiconductor regions 18 are disposed in an N-type well region 11. The third semiconductor region 6 is located closer to the second semiconductor region 5 than the first semiconductor region 4. The fourth semiconductor region 18 is located closer to the first semiconductor region 4 than the second semiconductor region 5.

FIG. 19 is a voltage waveform diagram of each terminal of the semiconductor device 1k according to the thirteenth embodiment. The first discharge terminal 9 is set at a voltage higher than a cathode voltage. The second discharge terminal 19 is set at a voltage lower than an anode voltage.

Thus, during the application of a reverse bias voltage to the PN junction diode 2, electrons in the depletion layer 12 are discharged to the first discharge terminal 9 through the third semiconductor region 6, and holes in the depletion layer 12 are discharged to the second discharge terminal 19 through the fourth semiconductor region 18. This can reduce both of a reverse current flowing to a cathode electrode 7 due to electrons in the depletion layer 12 and a reverse current flowing to an anode electrode 8 due to holes in the depletion layer 12.

The semiconductor substrates 10 in the semiconductor devices 1 to 1k according to the first to thirteenth embodiments may be made of silicon or other semiconductor materials. Semiconductor materials other than silicon may be, for example, SiGe, Ge, and SiC and III-V semiconductor materials such as InGaAs and GaAsSb.

### Fourteenth Embodiment

The semiconductor devices 1 according to the first to thirteenth embodiments are applicable to, for example, a photodetector. FIG. 20 is a block diagram illustrating a schematic configuration of a photodetector 21. The photodetector 21 of FIG. 20 includes a pixel array unit (light receiving unit) 22 and a negative-voltage generating circuit (voltage generating unit) 23.

The pixel array unit 22 includes a plurality of pixels 24 arranged in a one-dimensional or a two-dimensional direction. Each of the pixels 24 includes a SPAD (Single Photon Avalanche Diode) 25. The SPAD 25 is operable in a Geiger mode in which light is detectable for each photon. In order to operate the SPAD 25 in the Geiger mode, a predetermined reverse bias voltage needs to be applied to the SPAD 25. The negative-voltage generating circuit 23 generates a reverse bias voltage to be applied to each SPAD 25.

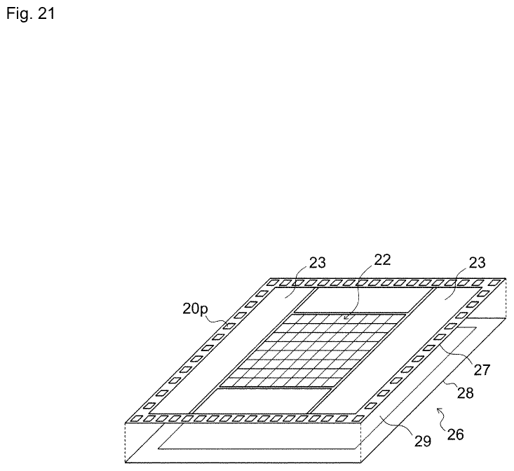

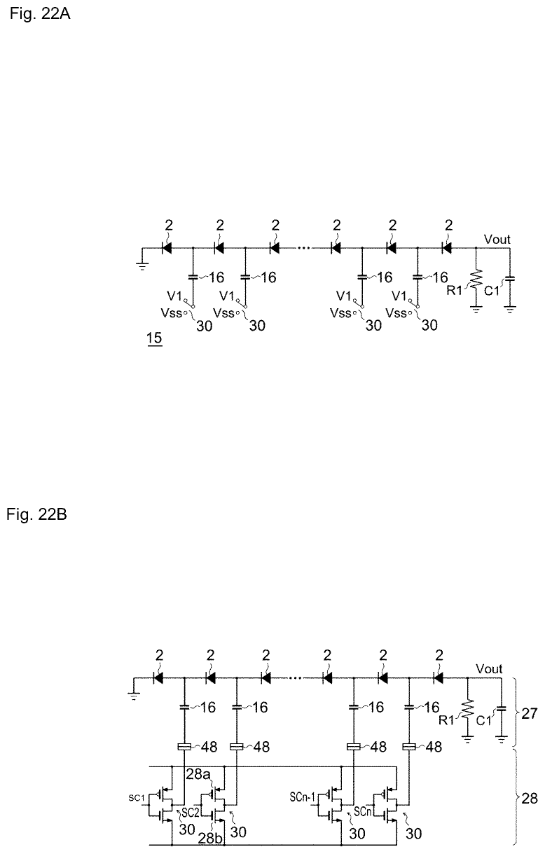

The photodetector 21 of FIG. 20 can be implemented by a semiconductor chip 26 having a laminated structure. FIG. 21 is a perspective view schematically illustrating the laminated structure of the semiconductor chip 26. The semiconductor chip 26 of FIG. 21 includes a first substrate 27 and a second substrate 28 that are stacked on top of each other. The first substrate 27 is disposed near a light entrance surface. The first substrate 27 and the second substrate 28 are joined to each other and transmit signals through, for example, vias or bumps.

On the first substrate 27, at least parts of the pixel array unit 22 and the negative-voltage generating circuit 23 are disposed. On the circumferential edge of the first substrate 27, a plurality of pads 20p for external wiring are disposed. On the second substrate 28, a logic circuit 29 is disposed to perform processing for AD conversion on a light receiving signal outputted from each pixel 24 in the pixel array unit 22 and various kinds of signal processing on AD-converted pixel data. The power-supply voltage level of the logic circuit 29 is quite lower than the absolute value of a negative voltage generated in the negative-voltage generating circuit 23. A part of the negative-voltage generating circuit 23 may be disposed on the first substrate 27, and the other part may be disposed on the second substrate 28.

Circuits at different voltage levels are separately disposed on the first substrate 27 and the second substrate 28 according to the present embodiment, thereby improving resistance to noise.

FIGS. 22A and 22B are circuit diagrams showing an example of the negative-voltage generating circuit 23. The negative-voltage generating circuit 23 includes a charge pump 15. FIG. 22A is a circuit diagram of the charge pump 15. The charge pump 15 in FIG. 22A includes PN junction diodes 2 cascaded in multiple stages, a plurality of capacitors 16, each being connected between the stages of the PN junction diodes 2 cascaded in the multiple stages, and a plurality of switches 30 connected in series with the plurality of capacitors 16. The charge pump 15 in FIG. 11A includes the plurality of driving circuits 17 instead of the plurality of switches 30. However, the driving circuit 17 can be configured with the switch 30, and thus the charge pump 15 in FIG. 22A is configured with substantially the same circuit as the charge pump 15 in FIG. 11A.

Among the PN junction diodes 2 in multiple stages, a cathode electrode 7 for the PN junction diode 2 of the first stage is set at a ground voltage, and a load resistor R1 and an output capacitor C1 are connected in parallel between an anode electrode 8 for the PN junction diode 2 of the final stage and a ground node. The output capacitor C1 may be externally mounted on the first substrate 27.

The switches 30 each switch whether to apply a predetermined voltage or a ground voltage to the other end of the corresponding capacitor 16. The switches 30 are sequentially turned on, so that a negative voltage corresponding to the number of stages of the PN junction diodes 2 can be outputted from the anode of the diode 2 of the final stage. The voltage level of a negative voltage can be adjusted by changing the number of stages of the connected PN junction diodes 2 or controlling the voltage level of a predetermined voltage applied to the other end of each of the switches 30.

FIG. 22B shows an example of a specific configuration of the plurality of switches 30 in the charge pump 15. As shown in FIG. 22B, each of the switches 30 includes a PMOS transistor 28a and an NMOS transistor 28b that are cascade-connected between a node for supplying a predetermined voltage and the ground node. To the gates of the PMOS transistors 28a and the NMOS transistors 28b in the switches 30, corresponding switching control signals SC1 to SCn are inputted. When the switching control signals SC1 to SCn reach a high level, the corresponding PMOS transistor 28a is turned off, the corresponding NMOS transistor 28b is turned on, and the other end of the corresponding capacitor 16 has a ground voltage. When the switching control signals SC1 to SCn reach a low level, the corresponding PMOS transistor 28a is turned on, the corresponding NMOS transistor 28b is turned off, and the other end of the corresponding capacitor 16 has a predetermined voltage V1.

As illustrated in FIG. 22B, the PN junction diodes 2 in multiple stages and the plurality of capacitors 16 in the charge pump 15 are disposed on the first substrate 27, and the plurality of switches 30 are disposed on the second substrate 28. The predetermined voltage V1 or a ground voltage Vss that is switched by the switch 30 is transmitted to the first substrate 27 through a junction 48 including a via or a bump. The plurality of switches 30 may be disposed on the first substrate 27.

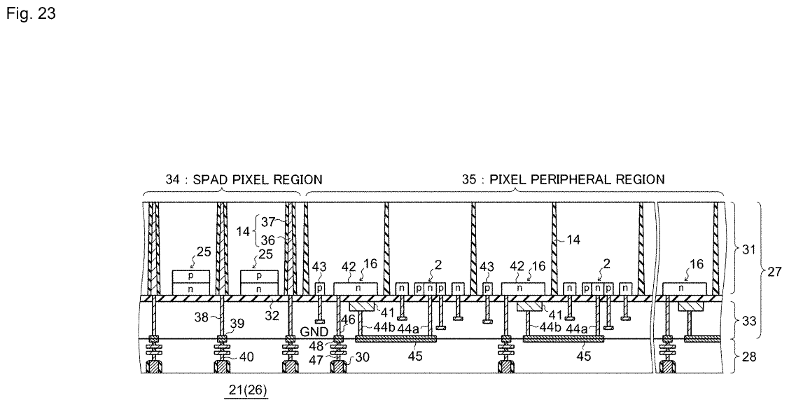

FIG. 23 is a cross-sectional view illustrating the first substrate 27 of the photodetector 21 in FIG. 20. As illustrated in FIG. 23, in the first substrate 27, an element formation region 31, an oxidation layer 32, and a wiring region 33 are sequentially disposed from the light entrance surface in the depth direction. The element formation region 31 includes a first region (hereinafter also referred to as a SPAD pixel region) 34, in which the pixel array unit 22 is disposed, and a second region (hereinafter also referred to as a pixel peripheral region) 35, in which peripheral circuits such as the negative-voltage generating circuit 23 are disposed, along the planar direction.

The SPAD pixel region 34 includes the pixel array unit 22 including the plurality of SPADs 25 arranged in a one-dimensional or two-dimensional direction. An element isolation region 14 extending in the depth direction is provided between the two adjacent SPADs 25. The element isolation region 14 in the SPAD pixel region 34 may have a laminated structure including a polysilicon layer 36 on the inner side and an insulating layer 37 made of SiO₂ or the like on the outer side. The polysilicon layer 36 is connected to a contact 40 in the second substrate 28 via a contact 38 and a via 39. The polysilicon layer 36 is set at, for example, the ground voltage.

In the pixel peripheral region 35, the PN junction diodes 2 of the stages in the charge pump 15 and the corresponding capacitors 16 are alternately disposed along the planar direction. The element isolation region 14 extending in the depth direction is disposed between the PN junction diode 2 and the corresponding capacitor 16. The element isolation region 14 is as deep as the element formation region 31.

The PN junction diodes 2 of the stages in the charge pump 15 are identical or similar in cross-section structure to the PN junction diodes 2 according to any one of the first to thirteenth embodiments. FIG. 23 shows an example in which the PN junction diodes 2 have the same cross-section structure as FIG. 9A.

The capacitor 16 connected between the stages of the PN junction diodes 2 includes two electrode layers 41 and 42 that are vertically disposed with the oxidation layer 32 interposed therebetween. The electrode layers 41 and 42 are made of, for example, polysilicon or a conductive material. Moreover, a semiconductor region 43 set at a ground potential is disposed near the electrode layer 41.

The anode of the PN junction diode 2 and the electrode layer 41 on one end of the corresponding capacitor 16 are electrically connected to each other at a junction 45 to the second substrate 28, via contacts 44a and 44b extending in the depth direction. The junction 45 is made of, for example, conductive materials such as Cu.

The electrode layer 42 on the other end of the capacitor 16 is joined at the junction 48 to a contact 47 of the second substrate 28 via a contact 46. The contact 47 of the second substrate 28 is connected to the switch 30 of the second substrate 28. In FIG. 23, the detailed cross-section structure of the switch 30 is omitted.

FIG. 23 illustrates an exemplary cross-section structure of the first substrate 27 of the photodetector 21. The structure may be modified in various forms. Thus, the cross-section structure of the first substrate 27 is not limited to that of FIG. 23.

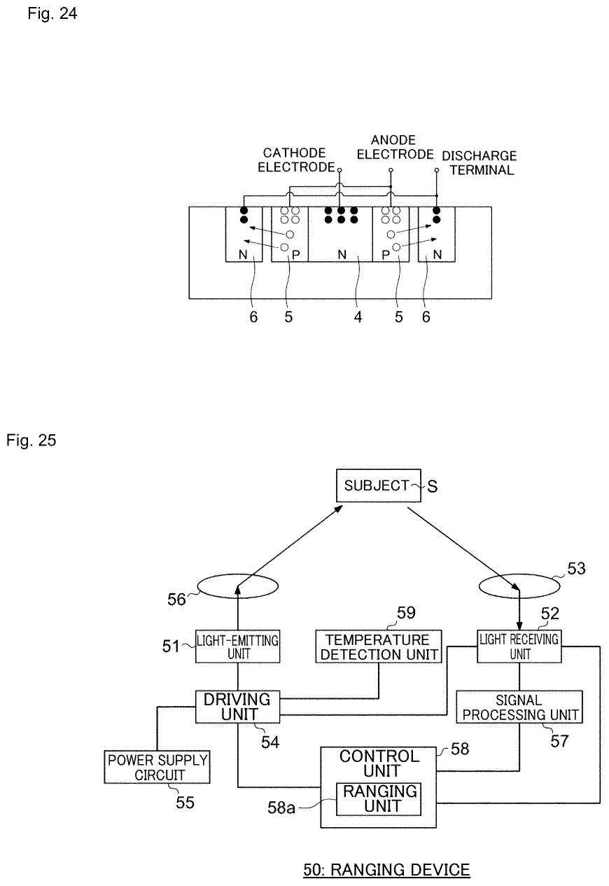

FIG. 24 is a cross-sectional view illustrating a cross-section structure of the capacitor 16 corresponding to the PN junction diode 2 in the charge pump 15. The PN junction diode 2 of FIG. 24 has the same cross-section structure as the PN junction diode 2 of FIG. 9A.

As illustrated in FIG. 24, the first semiconductor region 4 connected to the cathode electrode 7 in the PN junction diode 2 is N-type, the second semiconductor region 5 connected to the anode electrode 8 is P-type, and a third semiconductor region 6 connected to a discharge terminal 9 is N-type. A voltage higher than that of the cathode electrode 7 is applied to the discharge terminal 9 as in the first to tenth embodiments. Thus, when a reverse bias voltage is applied to the PN junction diode 2, electrons in a depletion layer 12 are quickly discharged to the discharge terminal 9 through the third semiconductor region 6.

A ranging device 50 having a ToF (Time of Flight) sensor can be constructed by combining the photodetector 21 of FIG. 21 and a light-emitting device that emits an optical signal. FIG. 25 is a block diagram illustrating a schematic configuration of the ranging device 50.

The ranging device 50 includes a light-emitting unit 51, a light receiving unit 52, a light-receiving side optical system (condenser lens) 53, a driving unit 54, a power supply circuit 55, a light-emitting side optical system 56, a signal processing unit 57, a control unit 58, and a temperature detection unit 59.

The light-emitting unit 51 emits light using a plurality of light sources. The light-emitting unit 51 includes, for example, a plurality of light-emitting elements using VCSELs (Vertical Cavity Surface Emitting LASER) as light sources and is configured such that the light-emitting elements are arranged in a predetermined form, e.g., a matrix. The light-emitting unit 51 corresponds to the photodetector 21 of FIG. 1.

The driving unit 54 has the power supply circuit 55 for driving the light-emitting unit 51. The power supply circuit 55 generates a power supply voltage of the driving unit 54 on the basis of, for example, an input voltage from a battery or the like, which is not illustrated, in the ranging device 50. The driving unit 54 drives the light-emitting unit 51 on the basis of the power supply voltage.

Light emitted from the light-emitting unit 51 is projected to a subject S, which is a target of ranging, through the light-emitting side optical system 56. Light reflected from the subject S enters the light receiving surface of the light receiving unit 52 through the light receiving side optical system 53.

The light receiving unit 52 can be configured with the photodetector 21. An imaging pixel irradiated with reflected light receives light reflected from the subject S through the light-receiving side optical system 53, converts the light into an electric signal, and outputs the signal.

For the electric signal obtained by photoelectrically converting the received light, for example, the light receiving unit 52 converts a voltage change, which is caused by a breakdown, into a digital signal and outputs the signal to the downstream signal processing unit 57.

Moreover, the light receiving unit 52 according to the present embodiment outputs a frame synchronizing signal to the driving unit 54. Thus, the driving unit 54 can cause the light-emitting elements in the light-emitting unit 51 to emit light with timing corresponding to the frame period of the light receiving unit 52.

The signal processing unit 57 is configured as a signal processor by, for example, a DSP (Digital Signal Processor). The signal processing unit 57 performs various kinds of signal processing on a digital signal inputted from the light receiving unit 52.

The control unit 58 is configured with a microcomputer including, for example, a CPU (Central Processing Unit), a ROM (Read Only Memory), and RAM (Random Access Memory) or is configured with an information processor such as a DSP. The control unit 58 controls the driving unit 54 to control a light-emitting operation by the light-emitting unit 51 and controls a light receiving operation by the light receiving unit 52.

The control unit 58 has a function as a ranging unit 60. The ranging unit 60 measures a distance to the subject S on the basis of a signal (that is, a signal obtained by receiving light reflected from the subject S) inputted through the signal processing unit 57. The ranging unit 60 according to the present embodiment measures a distance to each part of the subject S in order to identify the three-dimensional shape of the subject S.

The temperature detection unit 59 detects a temperature of the light-emitting unit 51. The temperature detection unit 59 may be configured to detect a temperature by using, for example, the diode 2.

Information about a temperature detected by the temperature detection unit 59 is supplied to the driving unit 54, so that the driving unit 54 can drive the light-emitting unit 51 on the basis of information about the temperature.

If a so-called direct ToF (dTOF) method is adopted as a ToF method, the light-emitting unit 51 performs pulse driving. In this case, the ranging unit 60 calculates a time difference from emission to reception of light that is emitted from the light-emitting unit 51 and is received by the light receiving unit 52, on the basis of a signal inputted through the signal processing unit 57, and the ranging unit 60 calculates a distance to each part of the subject S on the basis of the time difference and the speed of light.

If a so-called indirect ToF (iTOF) method is adopted as a ToF method, a distance is detected by the phase difference of a signal received by the light receiving unit 52.

### <Application to Mobile Object>

The technique of the present disclosure (the present technique) can be applied to various products. For example, the technique according to the present disclosure may be implemented as a device mounted on any type of mobile object such as an automobile, an electric automobile, a hybrid electric automobile, a motorcycle, a bicycle, a personal mobility device, an airplane, a drone, a ship, a robot, or the like.

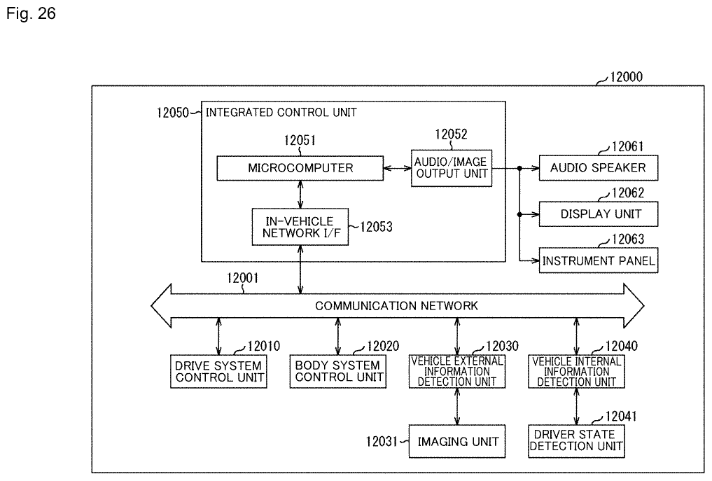

FIG. 26 is a block diagram showing a schematic configuration example of a vehicle control system that is an example of a mobile object control system to which the technique according to the present disclosure may be applied.

The vehicle control system 12000 includes a plurality of electronic control units connected to each other via a communication network 12001. In the example illustrated in FIG. 26, the vehicle control system 12000 includes a drive system control unit 12010, a body system control unit 12020, a vehicle external information detection unit 12030, a vehicle internal information detection unit 12040, and an integrated control unit 12050. As a functional configuration of the integrated control unit 12050, a microcomputer 12051, an audio/image output unit 12052, and an in-vehicle network I/F (Interface) 12053 are illustrated.

The drive system control unit 12010 controls an operation of an apparatus related to a drive system of a vehicle according to various programs. For example, the drive system control unit 12010 functions as a control apparatus for a driving force generator for generating a driving force of a vehicle such as an internal combustion engine or a driving motor, a driving force transmission mechanism for transmitting a driving force to wheels, a steering mechanism for adjusting a turning angle of a vehicle, and a braking apparatus that generates a braking force of a vehicle, and the like.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle external information detection unit 12030 detects information on the outside of the vehicle having the vehicle control system 12000 mounted thereon. For example, an imaging unit 12031 is connected to the vehicle external information detection unit 12030. The vehicle external information detection unit 12030 causes the imaging unit 12031 to capture an image of the outside of the vehicle and receives the captured image. The vehicle external information detection unit 12030 may perform object detection processing or distance detection processing for persons, cars, obstacles, signs, and letters on the road on the basis of the received image.

The imaging unit 12031 is an optical sensor that receives light and outputs an electrical signal according to the amount of the received light. The imaging unit 12031 can also output the electrical signal as an image or distance measurement information. In addition, the light received by the imaging unit 12031 may be visible light or invisible light such as infrared light.

The vehicle internal information detection unit 12040 detects information on the inside of the vehicle. For example, a driver state detection unit 12041 that detects a driver's state is connected to the vehicle internal information detection unit 12040. The driver state detection unit 12041 includes, for example, a camera that captures an image of a driver, and the vehicle internal information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of information inside and outside of the vehicle acquired by the vehicle external information detection unit 12030 or the vehicle internal information detection unit 12040, and output a control command to the drive system control unit 12010. For example, the microcomputer 12051 can perform cooperative control for the purpose of realizing functions of an ADAS (advanced driver assistance system) including vehicle collision avoidance, impact mitigation, following traveling based on an inter-vehicle distance, vehicle speed maintenance driving, vehicle collision warning, vehicle lane deviation warning, and the like.

Furthermore, the microcomputer 12051 can perform cooperative control for the purpose of automated driving or the like in which autonomous travel is performed without depending on operations of the driver, by controlling the driving force generator, the steering mechanism, or the braking device and the like on the basis of information about the surroundings of the vehicle, the information being acquired by the vehicle external information detection unit 12030 or the vehicle internal information detection unit 12040.

In addition, the microcomputer 12051 can output a control command to the body system control unit 12030 based on the information outside of the vehicle acquired by the vehicle external information detection unit 12030. For example, the microcomputer 12051 can perform coordinated control for the purpose of antiglare such as switching a high beam to a low beam by controlling a headlamp according to a position of a vehicle ahead or an oncoming vehicle detected by the vehicle external information detection unit 12030.

The audio/image output unit 12052 transmits an output signal of at least one of sound and an image to an output device capable of visually or audibly notifying a passenger or the outside of the vehicle of information. In the example of FIG. 26, an audio speaker 12061, a display unit 12062, and an instrument panel 12063 are illustrated as output devices. The display unit 12062 may include, for example, at least one of an onboard display and a heads-up display.

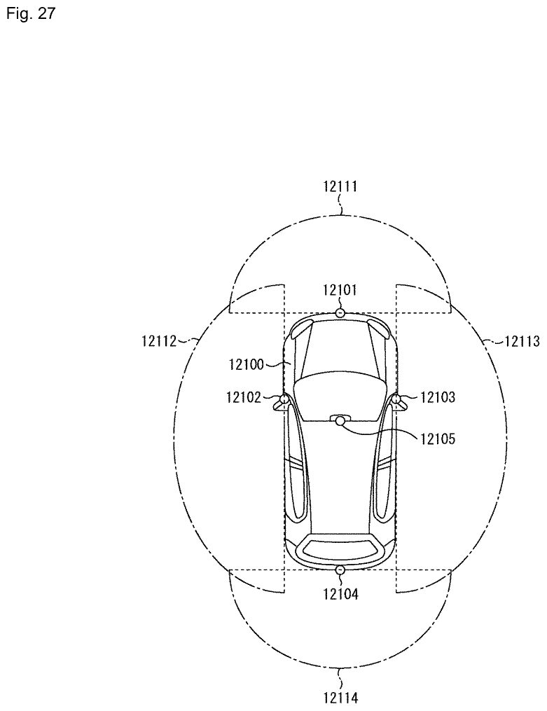

FIG. 27 is a diagram showing an example of an installation position of the imaging unit 12031.

In FIG. 27, the imaging unit 12031 includes imaging units 12101, 12102, 12103, 12104, and 12105.

The imaging units 12101, 12102, 12103, 12104, and 12105 are provided at, for example, positions of a front nose, side mirrors, a rear bumper, a back door, an upper portion of a vehicle internal front windshield, and the like of the vehicle 12100. The imaging unit 12101 provided on a front nose and the imaging unit 12105 provided in an upper portion of the vehicle internal front windshield mainly acquire images in front of the vehicle 12100. The imaging units 12102 and 12103 provided in the side mirrors mainly acquire images on the lateral sides of the vehicle 12100. The imaging unit 12104 included in the rear bumper or the back door mainly acquires an image of an area behind the vehicle 12100. The imaging unit 12105 included in the upper portion of the windshield inside of the vehicle is mainly used for detection of a vehicle ahead, a pedestrian, an obstacle, a traffic signal, a traffic sign, a lane, or the like.

Also, FIG. 27 shows an example of imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, by superimposing image data captured by the imaging units 12101 to 12104, it is possible to obtain a bird's-eye view image viewed from the upper side of the vehicle 12100.

At least one of the imaging units 12101 to 12104 may have a function for obtaining distance information. For example, at least one of the imaging units 12101 to 12104 may be a stereo camera constituted by a plurality of imaging elements or may be an imaging element that has pixels for phase difference detection.

For example, the microcomputer 12051 can extract, particularly, a closest three-dimensional object on a path through which the vehicle 12100 is traveling, which is a three-dimensional object traveling at a predetermined speed (for example, 0 km/h or higher) in the substantially same direction as the vehicle 12100, as a vehicle ahead by obtaining a distance to each three-dimensional object in the imaging ranges 12111 to 12114 and temporal change in the distance (a relative speed with respect to the vehicle 12100) based on distance information obtained from the imaging units 12101 to 12104. The microcomputer 12051 can also set a following distance to the vehicle ahead to be maintained in advance and perform automatic brake control (including following stop control) and automatic acceleration control (including following start control). It is therefore possible to perform coordinated control for the purpose of, for example, automated driving in which the vehicle travels in an automated manner without requiring the driver to perform operations.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging units 12101 to 12104 and can use the three-dimensional data to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or higher than a set value and there is a possibility of collision, an alarm is output to the driver through the audio speaker 12061 or the display unit 12062, forced deceleration or avoidance steering is performed through the drive system control unit 12010, and thus it is possible to perform driving support for collision avoidance.

At least one of the imaging units 12101 to 12104 may be an infrared camera that detects infrared rays. For example, the microcomputer 12051 can recognize a pedestrian by determining whether there is a pedestrian in the captured image of the imaging units 12101 to 12104. Such pedestrian recognition is performed by, for example, a procedure in which feature points in the captured images of the imaging units 12101 to 12104 as infrared cameras are extracted and a procedure in which pattern matching processing is performed on a series of feature points indicating an outline of an object to determine whether or not the object is a pedestrian. When the microcomputer 12051 determines that there is a pedestrian in the captured images of the imaging units 12101 to 12104 and the pedestrian is recognized, the audio/image output unit 12052 controls the display unit 12062 so that a square contour line for emphasis is superimposed and displayed with the recognized pedestrian. In addition, the audio/image output unit 12052 may control the display unit 12062 so that an icon indicating a pedestrian or the like is displayed at a desired position.

An example of the vehicle control system to which the technology according to the present disclosure can be applied has been described above. The technique according to the present disclosure is applicable to the imaging unit 12031 or the like among the above-described configurations. Specifically, the photodetector 21 of the present disclosure can be applied to the imaging unit 12031. By applying the technology according to the present disclosure to the imaging unit 12031, a clearer captured image can be obtained, which makes it possible to reduce driver fatigue.

The present technique can be configured as follows:

(1) A semiconductor device includes: a PN junction diode including an N-type first semiconductor region and a P-type second semiconductor region that are disposed in contact with each other at a PN junction surface;
a third semiconductor region that is separated from the first semiconductor region and the second semiconductor region and is provided for discharge in a depletion layer formed around the PN junction surface when a reverse bias voltage is applied to the PN junction diode;
a first electrode connected to the first semiconductor region;
a second electrode connected to the second semiconductor region; and
a third electrode connected to the third semiconductor region.

(2) The semiconductor device according to (1), wherein the third semiconductor region is disposed as high as the first semiconductor region and the second semiconductor region and is disposed closer to the second semiconductor region than the first semiconductor region.

(3) The semiconductor device according to (1), wherein the third semiconductor region is disposed as high as the first semiconductor region and the second semiconductor region and is disposed to surround the first semiconductor region and the second semiconductor region.

(4) The semiconductor device according to (1), wherein the first semiconductor region and the second semiconductor region are disposed near a first principal surface of a semiconductor substrate, and the third semiconductor region is disposed near a second principal surface opposite to the first principal surface of the semiconductor substrate.

(5) The semiconductor device according to (1), wherein the first semiconductor region and the second semiconductor region are disposed near a first principal surface of a semiconductor substrate, and

The third semiconductor region is disposed near a second principal surface opposite to the first principal surface of the semiconductor substrate and is disposed to surround the first semiconductor region and the second semiconductor region from a side of the second principal surface to a side of the first principal surface.

(6) The semiconductor device according to any one of (1) to (5), wherein the first semiconductor region, the second semiconductor region, and the third semiconductor region are disposed at the same layer height,
the second semiconductor region may be disposed to surround the first semiconductor region, and
the third semiconductor region is disposed to surround the second semiconductor region.

(7) The semiconductor device according to any one of (1) to (6), including a well region in which the first semiconductor region, the second semiconductor region, and the third semiconductor region are disposed, and an element isolation region disposed to surround the well region.

(8) The semiconductor device according to (7), wherein the element isolation region is as deep as or deeper than the first semiconductor region and the second semiconductor region.

(9) The semiconductor device according to (7), wherein the element isolation region is as deep as or deeper than the well region.

(10) The semiconductor device according to (7), wherein the element isolation region is disposed to penetrate a semiconductor substrate where the well region is disposed.

(11) The semiconductor device according to any one of (1) to (10), wherein the third semiconductor region is N-type, and
the third electrode discharges electrons in the depletion layer through the third semiconductor region when the reverse bias voltage is applied to the PN junction diode.

(12) The semiconductor device according to (11), wherein the first electrode is a cathode electrode, and
the third electrode is set at a higher voltage than the cathode electrode when the reverse bias voltage is applied to the PN junction diode.

(13) The semiconductor device according to (12), wherein the third electrode is set at the same voltage as the cathode electrode when a forward bias voltage is applied to the PN junction diode, and the third electrode is set at a higher voltage than the cathode electrode when the reverse bias voltage is applied to the PN junction diode.

(14) The semiconductor device according to any one of (1) to (10), wherein the third semiconductor region is P-type, and
the third electrode discharges holes in the depletion layer through the third semiconductor region when the reverse bias voltage is applied to the PN junction diode.

(15) The semiconductor device according to (14), wherein the second electrode is an anode electrode, and
the third electrode is set at a lower voltage than the anode electrode when the reverse bias voltage is applied to the PN junction diode.

(16) The semiconductor device according to (15), wherein the third electrode is set at the same voltage as the anode electrode when a forward bias voltage is applied to the PN junction diode, and the third electrode is set at a lower voltage than the anode electrode when the reverse bias voltage is applied to the PN junction diode.

(17) A photodetector including a light receiving element that receives an inputted optical signal; and
a voltage generating unit that generates a reverse bias voltage to be applied to the light receiving element,
wherein the voltage generating unit includes a charge pump that generates the reverse bias voltage with the PN junction diodes cascaded in multiple stages in the semiconductor device according to any one of (1) to (16).

(18) The photodetector according to (17), including: a first substrate; and a second substrate stacked on the first substrate,
wherein the first substrate may have a light receiving unit including the plurality of light receiving elements arranged in a one-dimensional or two-dimensional direction, and at least a part of the charge pump, and
the second substrate has a logic circuit driven at a voltage level lower than the absolute value of the reverse bias voltage.

(19) The photodetector according to (18), wherein the charge pump includes:
a plurality of capacitors, each being connected between the stages of the PN junction diodes cascaded in the multiple stages; and
a plurality of switches that switch the voltages of one ends of the plurality of capacitors,
the plurality of capacitors may be disposed on the first substrate, and
the plurality of switches are disposed on the second substrate.

(20) The photodetector according to (18) or (19), wherein the first substrate has an isolation layer that is disposed between at least some of the stages of the PN junction diodes in the multiple stages and extends in the depth direction of the first substrate.

(21) A method for driving a semiconductor device including: a PN junction diode including an N-type first semiconductor region and a P-type second semiconductor region that are disposed in contact with each other at a PN junction surface; and
a third semiconductor region that is separated from the first semiconductor region and the second semiconductor region, the method including:
providing a potential difference between a first electrode connected to the first semiconductor region so as to apply a reverse bias voltage to the PN junction diode and a second electrode connected to the second semiconductor region; and
applying a predetermined voltage to a third electrode connected to the third semiconductor region so as to move a charge in a depletion layer to the third semiconductor region, the depletion layer being disposed around the PN junction surface.

Aspects of the present disclosure are not limited to the aforementioned individual embodiments and include various modifications that those skilled in the art can achieve, and effects of the present disclosure are also not limited to the details described above. In other words, various additions, modifications, and partial deletion can be made without departing from the conceptual idea and the gist of the present disclosure that can be derived from the details defined in the claims and the equivalents thereof.

### REFERENCE SIGNS LIST

1, 1a, 1b, 1c, 1d, 1e, 1f, 1g, 1h, 1i, 1j, 1k Semiconductor device
2 PN junction diode
3 PN junction surface
4 First semiconductor region
5 Second semiconductor region
6,6a Third semiconductor region
7 First electrode (cathode electrode)
8 Second electrode (anode electrode)
9 Third electrode (discharge terminal, first discharge terminal)
10 Semiconductor substrate
11 N-type well region
11a P-type well region
12 Depletion layer
13 Recombination level
14, 14a, 14b, 14d Element isolation region
15 Charge pump
16 Capacitor
17 Driving circuit
18 Fourth semiconductor region
19 Fourth electrode (second discharge terminal)
20p Pad
21 Photodetector
22 Pixel array unit
23 Negative-voltage generating circuit
24 Pixel
26 Semiconductor chip
27 First substrate
28 Second substrate
28a PMOS transistor
28b NMOS transistor
29 Logic circuit
30 Switch
31 Element formation region
32 Oxidation layer
33 Wiring region
34 First region (SPAD pixel region)
35 Second region (pixel peripheral region)
36 Polysilicon layer
37 Insulating layer
38 Contact
39 Via
40 Contact
41 Electrode layer
42 Electrode layer
43 Semiconductor region
44a Contact
44b Contact
45 Junction
46 Contact
47 Contact
48 Junction
50 Ranging device
51 Light-emitting unit
52 Light receiving unit
53 Light-receiving side optical system (condenser lens)
53 Light-receiving side optical system
54 Driving unit
55 Power supply circuit
56 Light-emitting side optical system
57 Signal processing unit
58 Control unit
59 Temperature detection unit
60 Ranging unit

1. A semiconductor device comprising: a PN junction diode including an N-type first semiconductor region and a P-type second semiconductor region that are disposed in contact with each other at a PN junction surface;
a third semiconductor region that is separated from the first semiconductor region and the second semiconductor region and is provided for discharge in a depletion layer formed around the PN junction surface when a reverse bias voltage is applied to the PN junction diode;
a first electrode connected to the first semiconductor region;
a second electrode connected to the second semiconductor region; and
a third electrode connected to the third semiconductor region.

2. The semiconductor device according to claim 1, wherein the third semiconductor region is disposed as high as the first semiconductor region and the second semiconductor region and is disposed closer to the second semiconductor region than the first semiconductor region.

3. The semiconductor device according to claim 1, wherein the third semiconductor region is disposed as high as the first semiconductor region and the second semiconductor region and is disposed to surround the first semiconductor region and the second semiconductor region.

4. The semiconductor device according to claim 1, wherein the first semiconductor region and the second semiconductor region are disposed near a first principal surface of a semiconductor substrate, and the third semiconductor region is disposed near a second principal surface opposite to the first principal surface of the semiconductor substrate.

5. The semiconductor device according to claim 1, wherein the first semiconductor region and the second semiconductor region are disposed near a first principal surface of a semiconductor substrate, and the third semiconductor region is disposed near a second principal surface opposite to the first principal surface of the semiconductor substrate and is disposed to surround the first semiconductor region and the second semiconductor region from a side of the second principal surface to a side of the first principal surface.

6. The semiconductor device according to claim 1, wherein the first semiconductor region, the second semiconductor region, and the third semiconductor region are disposed at the same layer height,
the second semiconductor region is disposed to surround the first semiconductor region, and
the third semiconductor region is disposed to surround the second semiconductor region.

7. The semiconductor device according to claim 1, comprising a well region in which the first semiconductor region, the second semiconductor region, and the third semiconductor region are disposed, and
an element isolation region disposed to surround the well region.

8. The semiconductor device according to claim 7, wherein the element isolation region is as deep as or deeper than the first semiconductor region and the second semiconductor region.

9. The semiconductor device according to claim 7, wherein the element isolation region is as deep as or deeper than the well region.

10. The semiconductor device according to claim 7, wherein the element isolation region is disposed to penetrate a semiconductor substrate where the well region is disposed.

11. The semiconductor device according to claim 1, wherein the third semiconductor region is N-type, and
the third electrode discharges electrons in the depletion layer through the third semiconductor region when the reverse bias voltage is applied to the PN junction diode.

12. The semiconductor device according to claim 11, wherein the first electrode is a cathode electrode, and
the third electrode is set at a higher voltage than the cathode electrode when the reverse bias voltage is applied to the PN junction diode.

13. The semiconductor device according to claim 12, wherein the third electrode is set at the same voltage as the cathode electrode when a forward bias voltage is applied to the PN junction diode, and the third electrode is set at a higher voltage than the cathode electrode when the reverse bias voltage is applied to the PN junction diode.

14. The semiconductor device according to claim 1, wherein the third semiconductor region is P-type, and
the third electrode discharges holes in the depletion layer through the third semiconductor region when the reverse bias voltage is applied to the PN junction diode.

15. The semiconductor device according to claim 14, wherein the second electrode is an anode electrode, and
the third electrode is set at a lower voltage than the anode electrode when the reverse bias voltage is applied to the PN junction diode.

16. The semiconductor device according to claim 15, wherein the third electrode is set at the same voltage as the anode electrode when a forward bias voltage is applied to the PN junction diode, and the third electrode is set at a lower voltage than the anode electrode when the reverse bias voltage is applied to the PN junction diode.

17. A photodetector comprising a light receiving element that receives an inputted optical signal; and
a voltage generating unit that generates a reverse bias voltage to be applied to the light receiving element,
wherein the voltage generating unit includes a charge pump that generates the reverse bias voltage with the PN junction diodes cascaded in multiple stages in the semiconductor device according to claim 1.

18. The photodetector according to claim 17, comprising: a first substrate; and
a second substrate stacked on the first substrate,
wherein the first substrate has a light receiving unit including the plurality of light receiving elements arranged in a one-dimensional or two-dimensional direction, and at least a part of the charge pump, and
the second substrate has a logic circuit driven at a voltage level lower than an absolute value of the reverse bias voltage.

19. The photodetector according to claim 18, wherein the charge pump includes:
a plurality of capacitors, each being connected between the stages of the PN junction diodes cascaded in the multiple stages; and
a plurality of switches that switch voltages of one ends of the plurality of capacitors,
the plurality of capacitors are disposed on the first substrate, and
the plurality of switches are disposed on the second substrate.

20. The photodetector according to claim 18, wherein the first substrate has an isolation layer that is disposed between at least some of the stages of the PN junction diodes in the multiple stages and extends in a depth direction of the first substrate.
